(19) United States
(12) Patent Application Publication
(10) Pub. No.: US 2012/0119692 A1
(43) Pub. Date: May 17, 2012

(54) POWER GENERATOR OF HYBRID TYPE

(76) Inventor: Jae-Hak RYU, GOYANG-SI (KR)

(21) Appl. No.: 13/036,168

(22) Filed: Feb. 28, 2011

(30) Foreign Application Priority Data
Nov. 15, 2010 (KR) 10-2010-0113236

(51) Int. Cl. H02J 7/00; F03D 3/00; H01L 31/05

(52) U.S. Cl. 320/101

(57) ABSTRACT

A power generator generates electric power by using sunlight and wind force which are clean energies, and in particular a power generator of a hybrid type which is characterized in that electric power is mainly generated by using sunlight at daytime when it is sunny, and electric power can be alternatively generated by using wind force when there is not sunshine in case of a rainy weather or a cloudy weather or when wind is strong, so it is possible to generate electric power all the time by using sunlight and wind at both daytime and nighttime and sunny and cloudy weathers.

### CROSS REFERENCE

This application claims priority to Korean Patent Application Number 10-2010-0113236 filed on 15 Nov. 2010, the entire contents of which application is incorporated herein for all purposes by this reference.

### BACKGROUND OF THE INVENTION

As shown in FIG. 1A, a solar cell module 1 is configured like a solar cell 20 and a back sheet 30 are fixedly secured to the back side of a low iron content tempered glass 10 with the aid of an adhesive layer (EVA) (not shown).

The solar cell 20 applied to the solar cell module 1 is formed of a silicon single crystal and a poly crystal, so electric power is generated with the aid of a photoelectric effect of sunlight. The solar cell module 1 is able to generate electric power only at daytime when sunshine exists, namely, it is not able to generate electric power at nighttime when sunshine does not exist.

The solar cell module 1 orients South and South East or South West and is installed at an inclination angle of about 30° to 33° depending on the region of installation.

The sunlight electric power facility might be classified into a fixed type, a single-axis tracking type, a multiple-axis driving and tracking type and a light condensing type.

The fixed type has average 3.5 hours of sunshine amount at Daejun region where has the Korean average sunshine amount, about average 4 hours at Daegu region, and about average 6 hours at near equator.

The tracking type is characterized in that the solar cell module 1 moves along with sun and has about 15% power generation increase as compared to the fixed type that has only 3 to 6 hours of daily average power generation.

The light condensing type is basically directed to condensing sunshine at a silicon solar cell module by using a Fresnel lens or a mirror for thereby generating electric power, which is capable of generating 30% more power in minimum to 500% more power in maximum as compared to the fixed type, but when sunshine is inputted, ultraviolet rays, infrared rays or others are together inputted, which directly damage the materials of the solar cell module 1. Such damages might not be helpful for the solar cell module to generate electric power for a long time. The current light condensing type has a problem in the durability of the solar cell module.

The standard test condition (STC) of the solar cell module 1 consists of 25° C. of temperature, 1.5 of spectrum air mass, 1,000 W/m² of irradiance and has a problem that the efficiency decreases by 0.45˜0.55% when the temperature increases by 1°.

As compared to the above types, there is a wind force power generator as another environment friendly facility.

The wind force power generator 50 applied for generating electric power might be classified into a vertical axis type and a horizontal axis type. As shown in FIG. 1B, a horizontal axis type wind force power generator 50 generally represents a conventional propeller type wind force power generator which is lighter as compared to a vertical axis type produce in their same power generation capacities, and the manufacture of the same advantageously costs lower by about 20%, but the efficiency decreases, and the installation height is high due to the limited amount of wind.

The vertical axis wind force power generator has a little higher initial installation cost as compared to the horizontal axis type, and the wind force power generator weighs higher, but the rotation radius of each blade is small not having any limit in the direction of wind, and it is operable even with a small amount of wind.

The common horizontal axis wind force power generator generates depending on the speed of wind, normally at above 3 m/sec in average, but it is needed to have the speed at above 7 m/sec in order to obtain a normal level of power generation. In Korea, the speeds around coastal areas and Jeju island and Daegwanryung area are above 7 m/sec in average, where are optimum geographical areas for generating electric power.

The wind force power generator 50 is not easy to install at a city area having a lot of different geographical conditions, and in which the speeds of wind are not constant due to the direct effects of high rise buildings.

The wind force power generator 50 receives a very strong pressure at its rotary shaft when the instant speed of wind is above 30 m/sec, which might result in stopping generating power since the blades of generator might be broken.

In case of the fixed type solar cell module 1, the efficiency of power generation to area is 13˜15%, and the wind power generation is 20˜25%. The solar cell and wind force power generation methods are very environment friendly because clean sun and wind can be used unlimitedly, while generating less CO₂ which is a cause of earth warming problem and being the most representative energy sources among a lot of new regeneration energies.

Since the price of the silicon wafer sharply has decreased since the beginning of 2009, the unit price for power generation is currently US$2.0/Wp, and it is estimated that the unit cost will be US$1.5/Wp in 2012 and US1.0/Wp in 2020. When the unit price lowers, the unit price of the power generation might be similar with the unit price of power generation which uses fossil fuels, so Grid Parity point can be obtained, which means that everyone uses new regeneration energies instead of using fossil fuels.

The unit price of power generation of the solar cell module 1 is getting decreased, but wider installation areas are needed since energy density is low. In addition, it is impossible to generate at nighttime, and the wind force power generator 50 can generate both at daytime and nighttime, but there is an installation area limit, namely, the wind force power generator should be installed only at a place where has a lot of wind.

The sunshine power generator can be installed at any place without considering regional problems depending on the amount of sunshine, and maintenance cost is low, and it is possible to control the load of power usage during summer season, but the installation cost is very high, and a wider area is needed, and it is impossible to generate at nighttime.

In addition, the wind force generation method advantageously needs a very low installation cost, and power generation is possible to at both daytime and nighttime and needs less installation area as compared to the sunshine power generation method, but the wind force generation method is very limited to an installation place because it needs a quite high speed of wind, and maintenance is hard.

### SUMMARY OF THE INVENTION

The present invention relates to a power generator which generates electric power by using sunlight and wind force which are clean energies, and in particular to a power generator of a hybrid type which is characterized in that electric power is mainly generated by using sunlight at daytime when it is sunny, and electric power can be alternatively generated by using wind force when there is not sunshine in case of a rainy weather or a cloudy weather or when wind is strong, so it is possible to generate electric power all the time by using sunlight and wind at both daytime and nighttime and sunny and cloudy weathers.

It is an object of the present invention to provide a power generator of a hybrid type which overcomes the problems encountered in the conventional art.

It is another object of the present invention to provide a power generator of a hybrid type in which electric power can be generated by using sunshine when there is sunshine and electrical power can be alternatively generated by using a wind force when there is not sunshine, so it is possible to generate electric power all the time by using clean energy source irrespective of weather and time condition such as daytime and nighttime or sunny and cloudy weathers.

To achieve the above objects, there is provided a hybrid type power generator of an apparatus which generates electric power by using sunshine or wind force which are clean energies which comprises a frame which is made in a metallic structure arranged at a certain height; a sunshine electric power generation part which is fixed at an upper side of the frame and comprises a plurality of solar cell modules each having a plurality of solar cells for thereby generating electric power by using sunshine; a wind force electric power generation part which is fixed at a frame below the sunshine electric power generation part and comprises a plurality of blades rotating by the force of wind passing through a ventilation space formed at a lower side of the sunshine electric power generation part, with a lower end portion of each blade being connected with an electric power generation module, for thereby generating electric power with the aid of the rotations of the blades; and a control part which is connected with the sunshine electric power generation part and the wind force electric power generation part, respectively, and receives electric power and is electrically connected with a battery part for thereby supplying electric power to the battery part.

The power generator of a hybrid type according to the present invention makes it possible to generate electric power by using a sunshine power generation part when it is available to use sunshine or it is sunny or at daytime, and when it is windy, electric power can be generated by using a wind force power generation part, so the present invention makes it possible to generate power all the time irrespective of time and weather conditions such as daytime and nighttime or sunny and cloudy weathers.

It is preferred that the frame comprises a circular ring formed at its upper side, and a plurality of vertical members are downwardly extended below a lower side of the circular ring, and a lower side of each vertical member is equipped with a hollow waterproof casing, and the solar cell modules of the sunshine electric power generation part are installed at the inner side of the circular ring, and a plurality of blades of the wind force electric power generation part are rotatably installed at the inner sides of the vertical members, and an electric power generation module, a control part and a battery part are provided at the inner side of the waterproof casing.

The hybrid type power generator according to the present invention is characterized in that a solar cell module of the sunshine power generation part is arranged at the upper most portion, and a plurality of blades of the wind force power generation part rotate at a lower side of the same, and an electric facility consisting of a power generation module, a control part, a battery part and etc. are arranged at an inner side of a waterproof casing, so the hybrid type power generation apparatus can be installed outdoors and efficiently generate electric power.

It is preferred that the frame comprises a plurality of sharp needles formed at an upper side of the circular ring at regular intervals in a circumferential direction for preventing birds from sitting at the frame, which keeps the surfaces of the solar cell module of the sunshine electric power generation part clean from birds' secretions and droppings.

The surfaces of the hybrid type power generator can remain clean all the time by preventing the surface of the solar cell module from being polluted by birds' secretions or droppings for thereby enhancing sunshine power generation efficiency.

In the present invention, it is preferred that a circular ring is installed at a certain inclination angle for thereby helping install the solar cell module of the sunshine power generation part at a certain inclination angle, and a plurality of sharp needles are installed between the neighboring solar cell modules at regular intervals.

Therefore, the pollutants or dirt stacked on the surfaces of the solar cell module can naturally slide downwards and be removed with the aid of an inclination engaging structure of the solar cell module, while preventing birds from sitting on the solar cell module for thereby enhancing power generation efficiency.

It is preferred that the wind force electric power generation part is configured in such a manner that an upper end portion of the rotary shaft of each blade is rotatably secured to an upper side of the vertical member of the frame with the aid of a first bearing, and a lower side of the rotary shaft is rotatably secured to the center of the casing of the frame with the aid of a second bearing, and a lower end portion of the rotary shaft is connected to a rotor in the interior of the electric power generation module, and the plurality of the blades are extended in a radial direction about the rotary shaft, and a plurality of curved light weight rotation plates made of a glass fiber (FRP) are secured in a circumferential direction at regular intervals and rotate by the force of wind passing through a lower side of the solar cell module of the sunshine electric power generation part.

The present invention makes it possible to efficiently generate electric power with the aid of a power generation module which is designed to operate even when wind is weak since the blades weigh light.

It is preferred that four blades are arranged at the rotary shaft at a 90° interval from one another, with each rotation plate comprising a first curved part which bends in semicircular shape in one direction near the rotary shaft and a second curved part which bends in the opposed direction at an end portion of the first curved part, so the four rotation plates form a S-shaped cross section structure.

The wind which collides with a first curved part pushes each rotation plate in one direction with the aid of an S-shaped cross section of the rotation plate for thereby continuously rotating, along with the rotary shaft, the rotor installed in the power generation module connected with its lower side.

In the present invention, electric power is mainly generated by using sunlight at daytime when it is sunny, and electric power can be alternatively generated by using wind force. The electric power can be mainly generated by using a wind force power generation part in case of rainy day or cloudy day and at nighttime when it is not available to use sunshine.

In the above procedure, the sunshine power generation part is characterized in that a plurality of sharp needles are vertically fixed at an upper side of the frame at regular intervals in a circumferential direction, which results in preventing birds from sitting for thereby preventing the surface pollutions of the solar cell module of the sunshine power generation part due to birds' secretions or droppings, so it is possible to enhance power generation efficiencies when using sunshine.

The wind force power generation pat according to the present invention is characterized in that blades are extended in radial directions about a rotary shaft, and a plurality of curved light weight rotation plates made of glass fibers (FRP) are engaged at regular intervals in a circumferential direction for thereby allowing the blades to rotate with the aid of the wind which passes through the lower sides of the solar cell module of the sunshine power generation part, so even when wind is weak, the blades can rotate with the aid of their light weight structures for thereby reliably generating electric power.

The present invention is characterized in that the sunshine power generation part and/or the wind force power generation part can be concurrently operated or separately operated, so it is possible to generate electric power all the time by using clean energies of sunshine and wind force at both daytime and nighttime irrespective of weather conditions such as sunny or cloudy weathers.

### BRIEF DESCRIPTION OF THE DRAWINGS

The present invention will become better understood with reference to the accompanying drawings which are given only by way of illustration and thus are not limitative of the present invention, wherein;

FIG. 1A is a front and side cross sectional view illustrating a conventional solar cell module;

FIG. 1B is a perspective view illustrating a conventional wind force power generator;

FIG. 2 is a perspective view illustrating a hybrid type power generator according to the present invention;

FIG. 3 is a disassembled perspective view illustrating a hybrid type power generator according to the present invention;

FIG. 4 is a cross sectional view illustrating a structure that a solar cell module of a hybrid type power generator is horizontally arranged according to the present invention;

FIG. 5 is a cross sectional view illustrating a structure that a solar cell module of a hybrid type power generator is inclined at a certain angle according to the present invention; and

FIG. 6 is a view illustrating the entire constructions of a hybrid type power generator according to the present invention.

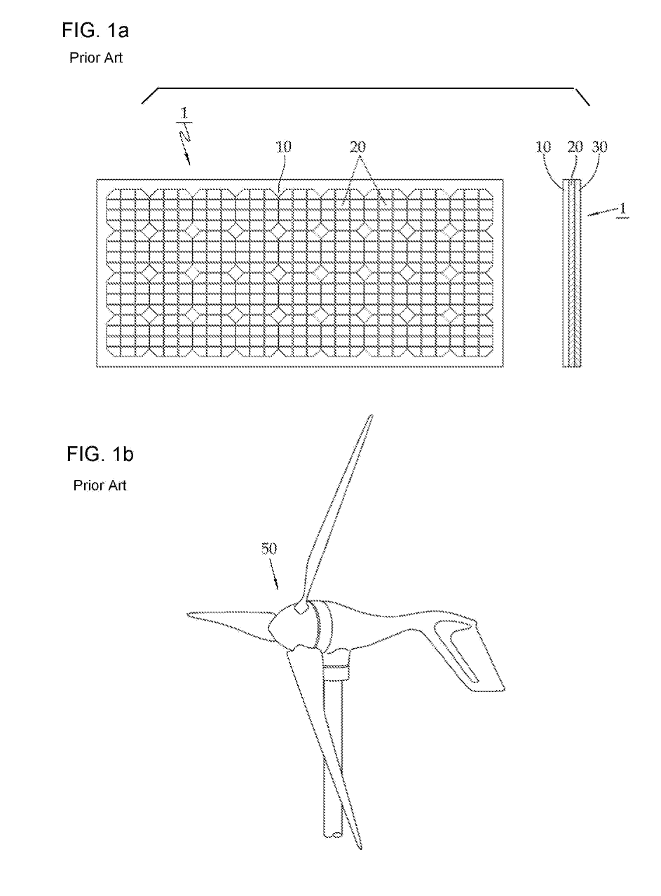

### DETAILED DESCRIPTION OF THE INVENTION

The preferred embodiments of the present invention will be described with reference to the accompanying drawings.

The hybrid type power generator 100 according to the present invention is basically directed to an apparatus for generating electric power by using sunshine and wind force which are clean energies.

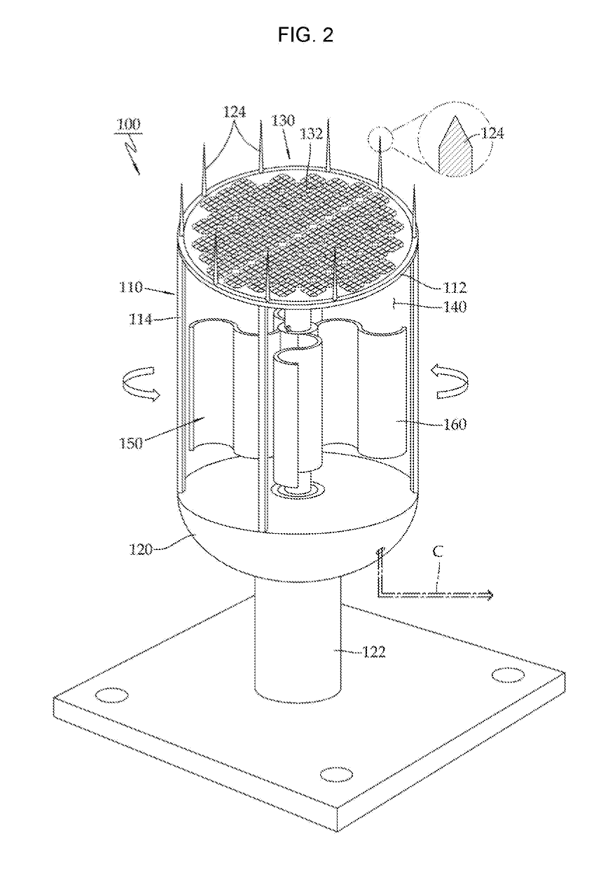

As shown in FIG. 2, the hybrid type power generator 100 according to the present invention is characterized in that a sunshine power generation part 130 and a wind force power generation part 150 are formed in one unit with the aid of a frame 110.

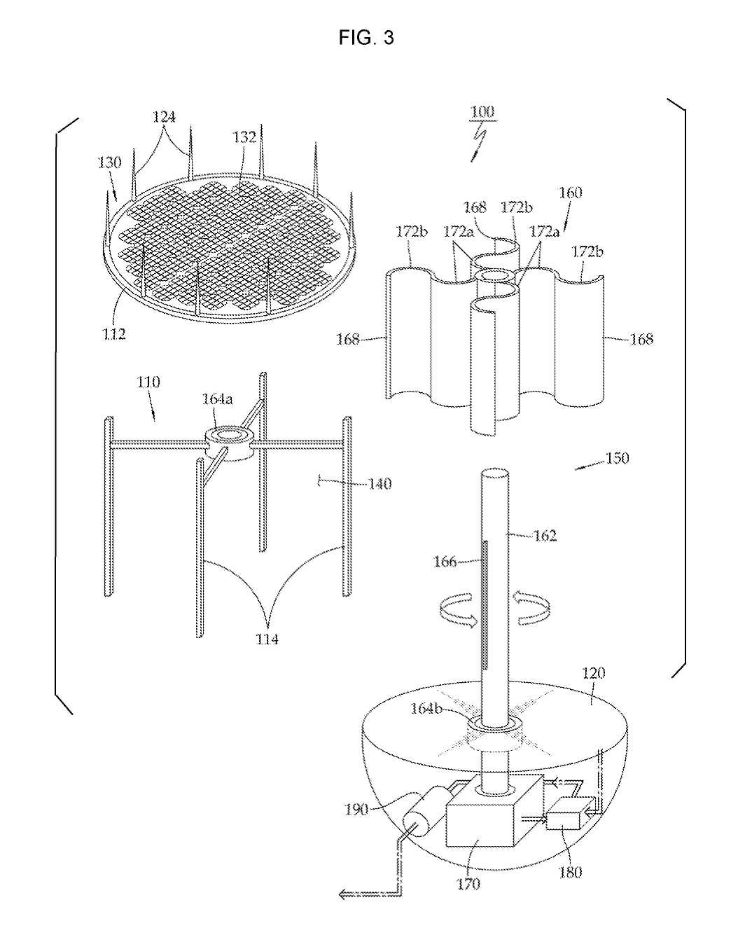

The frame 110 of the hybrid type power generator 100 according to the present invention is made of a metallic material such as aluminum or steel. As shown in FIG. 3, the frame 110 is supported at a certain height with the aid of a column 122, with a circular ring 112 being formed at an upper side of the frame 110, with a plurality of vertical members 114 being extended downwards toward a lower side of the circular ring 112, with a lower side of each vertical member 114 being equipped with a hollow waterproof casing 120.

In the frame 110, a solar cell module 132 of the sunshine power generation part 130 is arranged at an inner side of the circular ring 112, and a ventilation space 140 is formed at both a lower side of the sunshine power generation part 130 and an upper side of the casing 120. The ventilation space 140 is formed in the plurality of the vertical members 114, which makes it possible to form a structure whose four sides are open. The blades 160 of each wind force power generation part 150 are rotatably accommodated in the interior of the ventilation space 140. The waterproof casing 120 is arranged at a lower side of the ventilation space 140 of the vertical member 114.

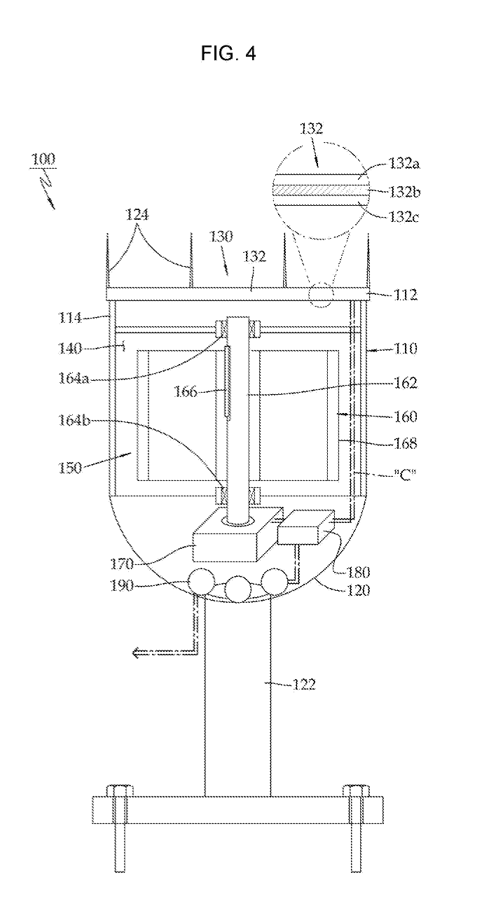

As shown in FIG. 4, in the hybrid type power generator 100 according to the present invention, the solar cell module 132 of the sunshine power generation part 130 is arranged at the upper most portion and the blades 160 of the wind force power generation part 150 rotate by wind below the solar cell module 132, and an electric facility consisting of a power generation module 170, a control part 180 and a battery part 190 at the inner side of the waterproof casing 120 is disposed below the same.

With the aid of the above constructions, the present invention makes it possible to efficiently use the entire spaces of the frame 110 without wasting spaces, which leads to efficiently arranging the sunshine power generation part 130 and the wind force power generation part 150, and high power generation efficiency can be obtained using a small size frame 110.

As shown in FIG. 2, the frame 110 is constituted in such a manner that a plurality of sharp needles 124 are arranged at regular intervals in a circumferential direction at an upper side of the circular ring 112. The needles 124 prevent birds from sitting at the frame 110, and it is possible to prevent any surface pollutions of the solar cell module 132 of the sunshine power generation part 130 due to birds' secretions and droppings. The entire surfaces of the solar cell module 132 can remain clean for thereby enhancing power generation efficiencies when generating power by using sunshine.

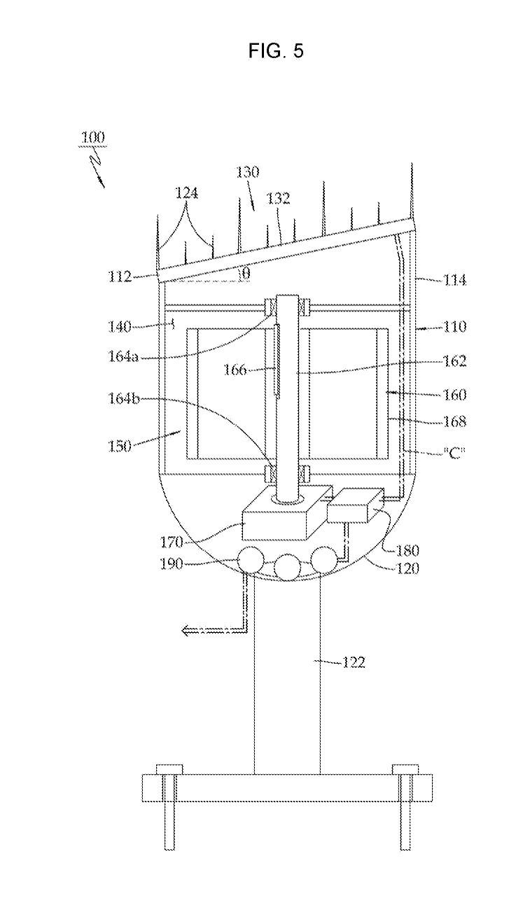

As shown in FIG. 5, it is preferred that the frame 110 is constituted in such a manner that the circular ring 112 is inclined at a certain angle θ, which helps install the solar cell module 132 of the sunshine power generation part 130 at a certain inclination angle. With the aid of the inclined engaging structure of the solar cell module 132, the pollutants or dirt stacked on the same can naturally slide downwards and be removed by means of rains or something, which forms a natural inclination discharge structure.

The plurality of the sharp needles 124 are arranged at the rim portions of the circular ring 112 as well as between the neighboring solar cell modules 132 at regular intervals.

The light weight aluminum needles 124 might be protruded upwards via the solar cell module 132 or the light weight aluminum needles 124 might be adhered to the surface of the solar cell module 132 by using an adhesive (not shown). The above constructions effectively help prevent birds from coming in and going out or sitting.

In the sunshine power generation part 130 engaged in a panel shape at the circular ring 112 of the upper side of the frame 110, each solar cell module 132 has an upper surface formed by using a low iron content tempered glass 132a, with a back surface of each solar cell module 132 being formed of a plurality of solar cells 132b and a back sheet 132c which are fixed with the aid of an adhering layer EVA.

The wind force power generation part 150 secured at the ventilation space 140 of the frame 110 has a plurality of blades 160 which rotate by using the force of wind which passes through the ventilation space 140.

As shown in FIG. 3, the wind force power generation part 150 is constituted in such a manner that the upper end portion of the rotary shaft 162 of the blades 162 is rotatably secured at the upper side of the vertical member 114 of the frame 110 with the aid of a first bearing 164a, and the lower side of the rotary shaft 162 is rotatably secured at the center portion of the casing 120 of the frame 110 with the aid of a second bearing 164b, with the lower end portion of the rotary shaft 162 being connected with a rotor (not shown) of the inner side of the power generation module 170.

In the above structure, the rotary shaft 162 and the blades 160 are integrally secured to each other at their securing portions with the aid of a key 166.

The blades 160 are extended in a radial direction about the rotary shaft 162, with a plurality of curved light weight rotation plates 168 made of a glass fiber (FRP) being arranged in a circumferential direction at regular intervals.

It is preferred that four rotation plates 168 are arranged at the rotary shaft 162 at a 90° angle interval from one another, respectively, and each rotation plate 168 is equipped with a first curved part 172a which bends in semicircular shape in one direction near the rotary shaft 162 and a second curved part 172b which bends in the opposed direction at an end portion of the first curved part 172a, so the four rotation plates form a S-shaped cross section structure.

With the aid of the S-shaped cross section structure, wind collided with the first curved part 172a pushes each rotation plate 168 in one direction and facilities each rotation plate to rotate between the first and second bearings 164a and 164b together with the rotary shaft 162, while continuously rotating the rotor of the power generation module 170 connected to the lower side.

Even when wind is weak, the rotation plates 168 can easily rotate with the aid of the light weight curved structure for thereby efficiently generating electric power by means of the power generation module 170.

The hybrid power generator 100 according to the present invention comprises a control part 180 which is electrically connected with the sunshine power generation part 130 and the wind force power generation part 150 to receive electric power and supply the received electric power to the battery part 190.

The controller 180 connects the sunshine power generation part 130 and the wind force power generation part 190, respectively, with a blocking diode being provided at a built-in anode terminal (not shown) for preventing a reverse flow of the electric power, so it is possible to prevent the electric power from reversely flowing toward the sunshine electric power generation part 130 and the wind force electric power generation part 150.

In the controller 180, the cathode terminals (not shown) from the sunshine electric power generation part 130 and the wind force electric power generation part 150 are connected with one common terminal.

In the present invention, the electric power can be received from the sunshine electric power generation part 130 and the wind force electric power generation part 150 by using one controller part and can be stored in the battery part 190. The electric power stored in the battery part 190 might be supplied to a certain place where a user wants to supply.

In the descriptions, character C means an electric power cable.

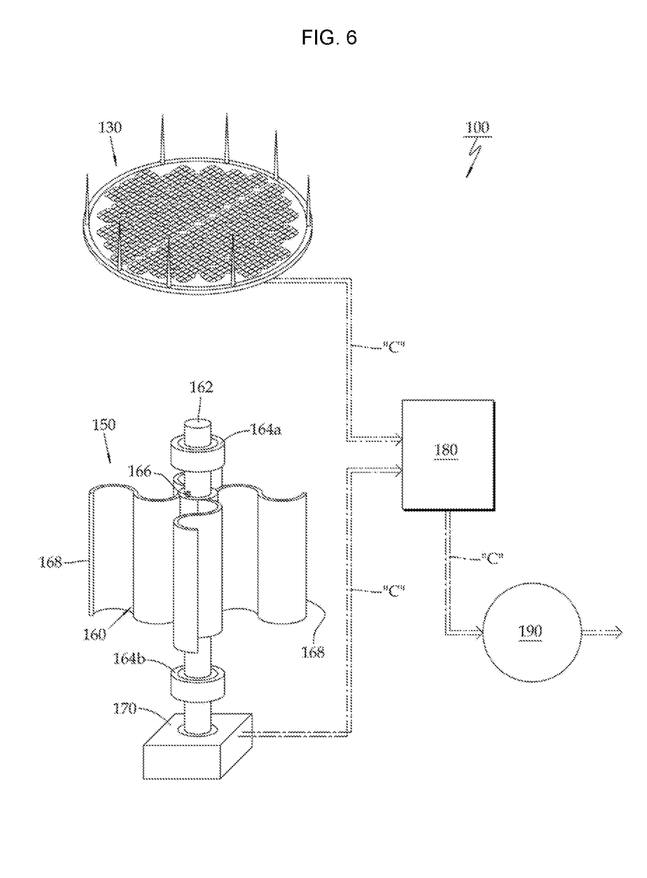

As shown in FIG. 6, the hybrid type power generator 100 according to the present invention makes it possible to constantly generate electric power at both daytime and nighttime and irrespective of weather conditions.

The sunshine electric power generation part 130 generates electric power at daytime when there is a lot of sunshine and stores the generated electric power into the battery part 190 with the aid of the control part 180, and when it is windy, the wind force electric power generation part 150 generates electric power separately from the sunshine electric power generation part 130.

When there is not wind, the wind force electric power generation part 150 cannot generate electric power. When it is sunny, the sunshine electric power generation part 130 generates, and since there is often wind when it is cloudy and rainy, the wind force electric power generation part 150 operates to generate electric power.

In particular, the wind force electric power generation part 150 can generate electric power whenever there is wind irrespective of daytime and nighttime.

At this time, the solar cell module 132 of the sunshine electric power generation part 130 is characterized in that a plurality of built-in solar cells 112b generate electric power with the aid of sunshine, and the generated electric power is stored into the battery part 190 with the aid of the control part 180.

The blades 160 of the wind force electric power generation part 150 rotate by wind together with the rotary shaft 162 for thereby rotating the rotor of the electric power generation module 170 connected to a lower side of the rotary shaft 162.

In this case, the electric power generation module 170 is equipped with a stator (not shown), with a rotor rotating inside the same, so the electric power generation modules generates electric power as the rotor rotates, and the generated electric power is stored into the battery part 190 with the aid of the control part 180.

During the procedure for generating electric power by using the sunshine electric power generation part 130 and the wind force electric power generation part 150, the plurality of the sharp needles 124 formed at the frame 110 or the solar cell module 132 can effectively prevent birds from sitting at the frame 110, as a result of which the surfaces of the solar cell module 132 of the sunshine electric power generation part 130 can be prevented from being polluted by birds' secretions and droppings. Since the surfaces of the solar cell module 132 can remain clean, not being polluted, it is possible to enhance power generation efficiencies when generating using sunshine.

In the present invention, the sunshine electric power generation part 130 generates electric power by using sunshine at daytime when it is sunny, and when there is wind, electric power can be generated by using the wind force electric power generation part 150. The wind force electric power generation part 150 can generate electric power when it is rainy or cloudy or at nighttime having no sunshine.

The present invention makes it possible to generate electric power all the time at both daytime and nighttime and irrespective of weather conditions such as sunny and cloudy weathers, so excellent energy substitute effects can be obtained.

The embodiments of the present invention have been described with reference to the accompanying drawings, but are not limited thereto. Those who skilled in the art can variously amend or change the present invention without departing from the basic concepts and claim ranges cited in the following claims. For example, it has been described that the frame 110 is equipped with a circular ring 112 for thereby securing the solar cell module 132, but the structure can be converted into a polygonal structure for example a rectangular shape, a hexagonal shape or an octagonal shape. However, it is obvious that even minor amendment or transformation of structure might belong to the scope of the present invention.

1. A hybrid type power generator of an apparatus which generates electric power by using sunshine or wind force which are clean energies, comprising:
a frame which is made in a metallic structure arranged at a certain height;
a sunshine electric power generation part which is fixed at an upper side of the frame and comprises a plurality of solar cell modules each having a plurality of solar cells for thereby generating electric power by using sunshine;
a wind force electric power generation part which is fixed at a frame below the sunshine electric power generation part and comprises a plurality of blades rotating by the force of wind passing through a ventilation space formed at a lower side of the sunshine electric power generation part, with a lower end portion of each blade being connected with an electric power generation module, for thereby generating electric power with the aid of the rotations of the blades; and
a control part which is connected with the sunshine electric power generation part and the wind force electric power generation part, respectively, and receives electric power and is electrically connected with a battery part for thereby supplying generated electric power to the battery part.

2. A hybrid type power generator according to claim 1, wherein said frame comprises a circular ring formed at its upper side, and a plurality of vertical members are downwardly extended below a lower side of the circular ring, and a lower side of each vertical member is equipped with a hollow waterproof casing, and the solar cell modules of the sunshine electric power generation part are installed at the inner side of the circular ring, and a plurality of blades of the wind force electric power generation part are rotatably installed at the inner sides of the vertical members, and an electric power generation module, a control part and a battery part are provided at the inner side of the waterproof casing.

3. A hybrid type power generator according to claim 1, wherein said frame comprises a plurality of sharp needles formed at an upper side of the circular ring at regular intervals in a circumferential direction for preventing birds from sitting at the frame, which keeps the surfaces of the solar cell module of the sunshine electric power generation part clean from birds' secretions and droppings.

4. A hybrid type power generator according to claim 3, wherein said frame is configured in such a manner that said circular ring is inclined at a certain angle, and the solar cell module of the sunshine electric power generation part is engaged at a certain inclined angle, and the plurality of the needles are fixedly arranged between the neighboring solar cell modules at regular intervals.

5. A hybrid type power generator according to claim 1, wherein said wind force electric power generation part is configured in such a manner that an upper end portion of the rotary shaft of each blade is rotatably secured to an upper side of the vertical member of the frame with the aid of a first bearing, and a lower side of the rotary shaft is rotatably secured to the center of the casing of the frame with the aid of a second bearing, and a lower end portion of the rotary shaft is connected to a rotor in the interior of the electric power generation module, and the plurality of the blades are extended in a radial direction about the rotary shaft, and a plurality of curved light weight rotation plates made of a glass fiber (FRP) are secured in a circumferential direction at regular intervals and rotate by the force of wind passing through a lower side of the solar cell module of the sunshine electric power generation part.

6. A hybrid type power generator according to claim 5, wherein four blades are arranged at the rotary shaft at a 90° interval from one another, with each rotation plate comprising a first curved part which bends in semicircular shape in one direction near the rotary shaft and a second curved part which bends in the opposed direction at an end portion of the first curved part, so the four rotation plates form a S-shaped cross section structure.
